(19) United States
(12) Patent Application Publication
(10) Pub. No.: US 2026/0068293 A1
(43) Pub. Date: Mar. 5, 2026

(54) SEMICONDUCTOR DEVICE STRUCTURE WITH TRANSISTOR AND RESISTOR AND METHOD FOR PREPARING THE SAME

(71) Applicant: NANYA TECHNOLOGY CORPORATION, NEW TAIPEI CITY (TW)

(72) Inventor: PING HSU, NEW TAIPEI CITY (TW)

(21) Appl. No.: 18/910,361

(22) Filed: Oct. 9, 2024

Related U.S. Application Data
(62) Division of application No. 18/823,948, filed on Sep. 4, 2024.

(51) Int. Cl. H01L 27/06; H01L 29/417; H01L 29/423

(52) U.S. Cl. CPC H10D 84/811; H10D 1/47; H10D 64/256; H10D 64/513

(57) ABSTRACT

The present application discloses a semiconductor device structure and a method for fabricating the semiconductor device structure. The semiconductor device structure includes a substrate; a transistor and a resistor disposed in the substrate; a plurality of isolation structures disposed in the substrate; a dielectric layer disposed over the substrate; and an interconnect structure disposed over and electrically connected to the transistor and the resistor. The transistor is disposed between a pair of the isolation structures, and the resistor is disposed between another pair of the isolation structures.

### CROSS-REFERENCE TO RELATED APPLICATION

This application is a divisional application of U.S. Non-Provisional application Ser. No. 18/823,948 filed Sep. 4, 2024, which is incorporated herein by reference in its entirety.

### TECHNICAL FIELD

The present disclosure relates to a semiconductor device structure and a method for preparing the same, and more particularly, to a semiconductor device structure with a transistor and a resistor and a method for preparing the same.

### DISCUSSION OF THE BACKGROUND

Semiconductor devices are used in various electronic applications, including personal computers, cellular telephones, digital cameras, and other electronic equipment. Sizes of semiconductor devices are continuously decreasing to meet the growing demand for computing power. However, such scaling down presents challenges that are becoming more frequent and impactful. Therefore, there are still challenges to overcome in improving quality, yield, performance and reliability while reducing complexity.

The manufacturing and integration of semiconductor devices involve many complicated steps and operations. Integration in semiconductor devices is becoming increasingly complicated. An increase in complexity of manufacturing and integrating the semiconductor device may cause deficiencies. For example, a smaller resistor formed by a conventional process flow may exhibit insufficient sheet resistance. Accordingly, there is a continuous need to improve the structure and manufacturing process of semiconductor devices so that the deficiencies can be addressed, and the performance can be enhanced.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device structure. The semiconductor device structure comprises a substrate; a transistor and a resistor disposed in the substrate; a plurality of isolation structures disposed in the substrate, wherein the transistor is disposed between a pair of isolation structures and the resistor is disposed between another pair of isolation structures; a dielectric layer disposed over the substrate; and an interconnect structure disposed over and electrically connected to the transistor and the resistor.

In some embodiments, the transistor comprises a gate electrode; a plurality of source/drain (S/D) regions disposed on either side of the gate electrode; and a first portion of the dielectric layer disposed between the gate electrode and the substrate.

In some embodiments, the resistor comprises a resistor electrode; a well region disposed below the resistor electrode; and a second portion of the dielectric layer disposed between the resistor electrode and the well region.

In some embodiments, one of the isolation structures is disposed between the transistor and the resistor, and the one isolation structure is closer to the resistor than to the transistor.

In some embodiments, the interconnect structure comprises a plurality of conductive contacts disposed over corresponding source/drain (S/D) regions of the transistor; a plurality of conductive vias disposed over and electrically connected to the resistor electrode of the resistor; and a plurality of conductive layers disposed over the conductive contacts and the conductive vias, and electrically connected to the source/drain (S/D) regions of the transistor and to the resistor electrode of the resistor.

In some embodiments, the conductive contacts penetrate through the dielectric layer into the source/drain (S/D) regions.

In some embodiments, each of the conductive contacts comprises a conductive via surrounded by a barrier layer.

In some embodiments, the barrier layers comprise a first thickness on sidewalls of the corresponding conductive vias and a second thickness under bottom surfaces of the corresponding conductive vias.

In some embodiments, the first thickness of the barrier layers is less than the second thickness of the barrier layers.

In some embodiments, the semiconductor device structure further comprises an interlayer-dielectric (ILD) layer disposed between the dielectric layer and the conductive layers, and surrounding the conductive contacts and the conductive vias of the interconnect structure.

Another aspect of the present disclosure provides a semiconductor device structure. The semiconductor device structure comprises a plurality of source/drain (S/D) regions disposed in a substrate; a dielectric layer disposed over the source/drain regions; and a conductive contact penetrating through the dielectric layer into the source/drain regions. The conductive contact comprises a conductive via and a barrier layer covering sidewalls and a bottom surface of the conductive via. A first thickness of the barrier layer on the sidewalls of the conductive via is less than a second thickness of the barrier layer under the bottom surface of the conductive via.

In some embodiments, the semiconductor device structure further comprises an interlayer-dielectric (ILD) layer disposed over the dielectric layer and surrounding the conductive contact; and a conductive layer disposed over the ILD layer.

In some embodiments, the semiconductor device structure further comprises an isolation structure disposed in the substrate to define a first active region and a second active region; and a conductive structure disposed in the substrate and over the isolation structure.

In some embodiments, the semiconductor device structure further comprises a gate electrode disposed in the first active region and between the source/drain (S/D) regions, and a resistor electrode disposed in a well region in the second active region.

In some embodiments, the gate electrode is electrically connected to the resistor electrode through the conductive structure.

In some embodiments, a first portion of the dielectric layer is disposed between the gate electrode and the substrate, and a second portion of the dielectric layer is disposed between the resistor electrode and the well region.

Another aspect of the present disclosure provides a semiconductor device structure. The semiconductor device structure comprises a substrate having a plurality of isolation structures disposed therein, wherein the plurality of isolation structures define a first active region and a second active region of the substrate; a plurality of source/drain (S/D) regions disposed in the first active region and a well region disposed in the second active region; a gate electrode and a resistor electrode disposed in the substrate, wherein the gate electrode is disposed between a pair of the source/drain (S/D) regions, and the resistor electrode is disposed over the well region; a dielectric layer disposed over the substrate, wherein a first portion of the dielectric layer is disposed between the gate electrode and the substrate, and a second portion of the dielectric layer is disposed between the resistor electrode and the substrate; an interlayer-dielectric (ILD) layer disposed over the dielectric layer, the gate electrode and the resistor electrode; a plurality of conductive contacts disposed on the plurality of source/drain (S/D) regions; and a plurality of conductive layers disposed over the ILD layer.

In some embodiments, each of the conductive contacts comprises a lower portion protruding into a corresponding S/D region, and an upper portion disposed on the lower portion and interposed between a top surface of the substrate and the conductive layers.

In some embodiments, the lower portions of the conductive contacts in the substrate are not in direct contact with any of the plurality of isolation structures in the substrate.

In some embodiments, the lower portions of the conductive contacts comprise a first critical dimension and the upper portions of the conductive contacts comprise a second critical dimension, wherein the second critical dimension is greater than the first critical dimension.

In some embodiments, the first critical dimension of the lower portions gradually decreases at positions of increasing distance from the top surface of the substrate, while the second critical dimension of the upper portions is constant.

In some embodiments, peripheral surfaces of the lower portions of the conductive contacts are respectively discontinuous with peripheral surfaces of the upper portions of the conductive contacts.

In some embodiments, the well region adjoins the isolation structures in the second active region.

In some embodiments, the semiconductor device structure further comprises a plurality of conductive vias disposed over and electrically connected to the resistor electrode.

In some embodiments, the conductive contacts, the conductive vias and the conductive layers together configure an interconnect structure.

Another aspect of the present disclosure provides a semiconductor device structure. The semiconductor device structure comprises a source/drain (S/D) region disposed in a substrate; a conductive layer disposed over the substrate; and a conductive contact comprising a lower portion protruding into the S/D region and an upper portion disposed on the lower portion and interposed between a top surface of the substrate and the conductive layer.

In some embodiments, the lower portion of the conductive contact comprises a first critical dimension and the upper portion of the conductive contact comprises a second critical dimension, wherein the second critical dimension is greater than the first critical dimension.

In some embodiments, the semiconductor device structure further comprises a plurality of isolation structures disposed in the substrate, wherein the lower portion of the conductive contact in the substrate is not in direct contact with any of the plurality of isolation structures in the substrate.

In some embodiments, the first critical dimension of the lower portion gradually decreases at positions of increasing distance from the top surface of the substrate, while the second critical dimension of the upper portions is constant.

In some embodiments, a peripheral surface of the lower portion of the conductive contact is discontinuous with a peripheral surface of the upper portion of the conductive contact.

Another aspect of the present disclosure provides a method of fabricating a semiconductor device. The method comprises providing a semiconductor substrate; forming a plurality of isolation structures and a well region in the semiconductor substrate; recessing the semiconductor substrate to form a plurality of openings between the isolation structures; depositing a dielectric layer over the semiconductor substrate to form a first opening and a second opening in the substrate, wherein the dielectric layer extends into the first opening and the second opening; forming an electrode layer over the dielectric layer, wherein the first opening and the second opening are filled by the electrode layer; performing one or more ion implantation process on the electrode layer; polishing the electrode layer to form a gate electrode and a resistor electrode; forming a plurality of source/drain regions in the semiconductor substrate and on opposite sides of the gate electrode; forming an interlayer-dielectric layer over the dielectric layer; etching the interlayer-dielectric layer and the dielectric layer to form a third opening and a fourth opening in the interlayer-dielectric layer, and form an etched interlayer-dielectric layer over the semiconductor substrate; forming a plurality of conductive contacts in the third opening, and forming a plurality of conductive vias in the fourth opening; and forming an interconnect structure over the etched interlayer-dielectric layer, the conductive contacts and the conductive vias.

In some embodiments, the formation of the conductive contacts in the third opening, and the formation of the conductive vias in the fourth opening comprises forming a sacrificial liner on sidewalls of the third opening; performing an etching process to form a contact hole in the source/drain regions and connected to the third opening; removing the sacrificial liner to form the fifth opening; and filling a conductive material in the fourth opening, the fifth opening and the contact hole.

In some embodiments, the conductive contact comprises a lower portion disposed in the S/D region and an upper portion disposed over the lower portion, wherein the upper portion interposed between a top surface of the semiconductor substrate and the interconnect structure.

In some embodiments, the lower portion comprise a first critical dimension and the upper portion comprise a second critical dimension, wherein the second critical dimension is greater than the first critical dimension.

In some embodiments, the first critical dimension of the lower portion gradually decreases at positions of increasing distance from the top surface of the substrate, while the second critical dimension of the upper portion is constant.

Embodiments of semiconductor device structures are provided in the disclosure. The semiconductor device structures include a transistor (e.g., a PMOS transistor or an NMOS transistor) and a resistor connected in series and formed by an integrated process flow. Particularly, a gate electrode of the transistor and a resistor electrode of the resistor are formed in a semiconductor substrate by a same process step. Therefore, the resistor may exhibit high sheet resistance without using additional masks or process steps. As a result, associated costs may be reduced, and a performance of the semiconductor device structures may be improved.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor device structure in accordance with some embodiments of the present disclosure.

FIG. 2 is a circuit diagram of the semiconductor device structure in FIG. 1.

FIG. 3 is a cross-sectional view of a modified semiconductor device structure in accordance with some embodiments of the present disclosure.

FIG. 4 is a cross-sectional view of another modified semiconductor device structure in accordance with some embodiments of the present disclosure.

FIG. 5 is a cross-sectional view of yet another modified semiconductor device structure in accordance with some embodiments of the present disclosure.

FIG. 6 is a flow diagram of a method for preparing a semiconductor device structure in accordance with some embodiments of the present disclosure.

FIG. 7 is a cross-sectional view of an intermediate stage of preparing isolation structures and a well region during the formation of the semiconductor device structure in accordance with some embodiments of the present disclosure.

FIG. 8 is a cross-sectional view of an intermediate stage of preparing openings between the isolation structures during the formation of the semiconductor device structure in accordance with some embodiments of the present disclosure.

FIG. 9 is a cross-sectional view of an intermediate stage of preparing a dielectric layer during the formation of the semiconductor device structure in accordance with some embodiments of the present disclosure.

FIG. 10 is a cross-sectional view of an intermediate stage of preparing an electrode layer during the formation of the semiconductor device structure in accordance with some embodiments of the present disclosure.

FIG. 11 is a cross-sectional view of an intermediate stage of performing an ion implantation process on the electrode layer during the formation of the semiconductor device structure in accordance with some embodiments of the present disclosure.

FIG. 12 is a cross-sectional view of an intermediate stage of performing an ion implantation process on the electrode layer during the formation of the semiconductor device structure in accordance with some embodiments of the present disclosure.

FIG. 13 is a cross-sectional view of an intermediate stage of polishing the electrode layer during the formation of the semiconductor device structure in accordance with some embodiments of the present disclosure.

FIG. 14 is a cross-sectional view of an intermediate stage of preparing source/drain regions during the formation of the semiconductor device structure in accordance with some embodiments of the present disclosure.

FIG. 15 is a cross-sectional view of an intermediate stage of preparing an interlayer-dielectric layer during the formation of the semiconductor device structure in accordance with some embodiments of the present disclosure.

FIG. 16 is a cross-sectional view of an intermediate stage of preparing a patterned mask over the interlayer-dielectric layer during the formation of the semiconductor device structure in accordance with some embodiments of the present disclosure.

FIG. 17 is a cross-sectional view of an intermediate stage of partially removing the interlayer-dielectric layer and the dielectric layer during the formation of the semiconductor device structure in accordance with some embodiments of the present disclosure.

FIG. 18 is a cross-sectional view of an intermediate stage of performing an ion implantation process on the electrode layer during the formation of the semiconductor device structure in accordance with some embodiments of the present disclosure.

FIG. 19 is a cross-sectional view of an intermediate stage of performing an ion implantation process on the electrode layer during the formation of the semiconductor device structure in accordance with some embodiments of the present disclosure.

FIG. 20 is a cross-sectional view of an intermediate stage of preparing an opening in a semiconductor substrate during the formation of the semiconductor device structure in accordance with some embodiments of the present disclosure.

FIG. 21 is a cross-sectional view of an intermediate stage of preparing a conductive layer during the formation of the semiconductor device structure in accordance with some embodiments of the present disclosure.

FIG. 22 is a cross-sectional view of an intermediate stage of preparing a conductive structure during the formation of the semiconductor device structure in accordance with some embodiments of the present disclosure.

FIG. 23 is a cross-sectional view of an intermediate stage of preparing a liner during the formation of the semiconductor device structure in accordance with some embodiments of the present disclosure.

FIG. 24 is a cross-sectional view of an intermediate stage of preparing a contact hole during the formation of the semiconductor device structure in accordance with some embodiments of the present disclosure.

FIG. 25 is a cross-sectional view of an intermediate stage after removing the liner during the formation of the semiconductor device structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

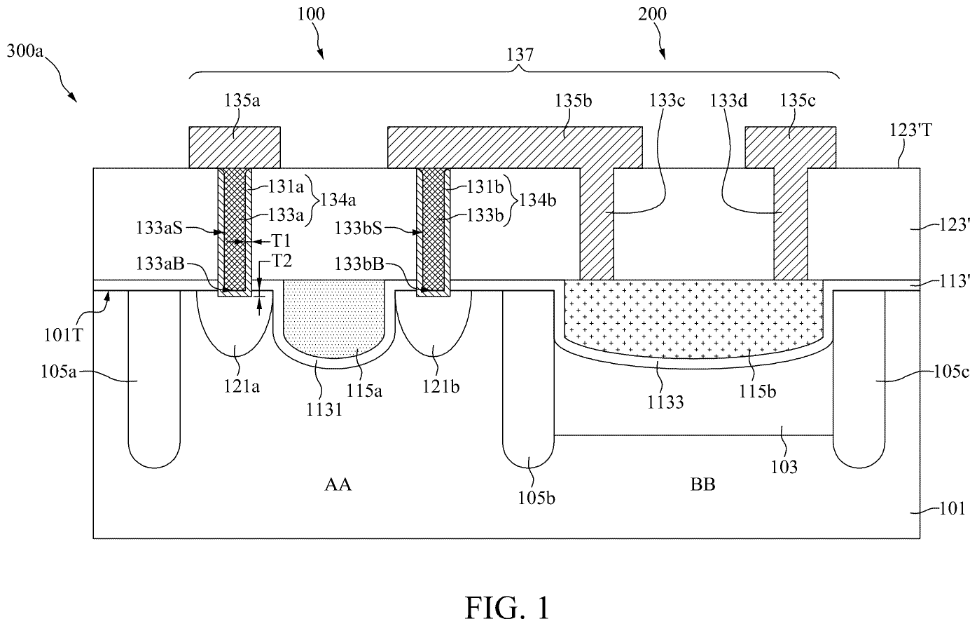

FIG. 1 is a cross-sectional view of a semiconductor device structure 300a in accordance with some embodiments of the present disclosure. With reference to FIG. 1, the semiconductor device structure 300a includes a semiconductor substrate 101, a transistor 100 and a resistor 200. The semiconductor substrate 101 includes a plurality of isolation structures 105a, 105b and 105c disposed therein. The isolation structures 105a and 105b define an active region AA of the transistor 100, and the isolation structures 105b and 105c define an active region BB of the resistor 200. It should be noted that a number of the isolation structures in the semiconductor device structure is not limited to three, and may be less or more.

In some embodiments, the semiconductor device structure 300a also includes a gate electrode 115a and source/drain (S/D) regions 121a, 121b in the active region AA of the transistor 100 (i.e., between the isolation structures 105a and 105b). The gate electrode 115a is located between the S/D regions 121a and 121b, and the gate electrode 115a and the S/D regions 121a, 121b are disposed in the semiconductor substrate 101.

In some embodiments, the semiconductor device structure 300a further includes a well region 103 and a resistor electrode 115b in the active region BB of the resistor 200 (i.e., between the isolation structures 105b and 105c). The well region 103 and the resistor electrode 115b are disposed in the semiconductor substrate 101, and the resistor electrode 115b is disposed over the well region 103. In addition, the well region 103 adjoins the isolation structures 105b and 105c. It should be noted that, in accordance with some embodiments, the isolation structure 105b between the active region AA of the transistor 100 and the active region BB of the resistor 200 is closer to the resistor electrode 115b than to the gate electrode 115a.

Moreover, in accordance with some embodiments, the semiconductor device structure 300a includes a dielectric layer 113′ disposed over the semiconductor substrate 101. In particular, the dielectric layer 113′ has a first portion 1131 and a second portion 1133, wherein both the first portion 1131 and the second portion 1133 are lower than a top surface 101T of the semiconductor substrate 101, the first portion 1131 is between the gate electrode 115a and the semiconductor substrate 101, and the second portion 1133 is between the resistor electrode 115b and the semiconductor substrate 101. In some embodiments, the gate electrode 115a is separated from the semiconductor substrate 101 by the first portion 1131 of the dielectric layer 113′, and the resistor electrode 115b is separated from the well region 103 in the semiconductor substrate 101 by the second portion 1133 of the dielectric layer 113′.

In addition, in some embodiments, the resistor electrode 115b is separated from the isolation structures 105b and 105c by the second portion 1133 of the dielectric layer 113′. In some embodiments, the isolation structures 105a, 105b and 105c are covered by the dielectric layer 113′, and the S/D regions 121a and 121b are partially covered by the dielectric layer 113′.

Still referring to FIG. 1, in accordance with some embodiments, the semiconductor device structure 300a comprises an interlayer-dielectric (ILD) layer 123′ disposed over the dielectric layer 113′, and an interconnect structure 137 disposed over and protruding into the ILD layer 123′. More specifically, the interconnect structure 137 comprises a plurality of conductive contacts 134a and 134b, a plurality of conductive vias 133c and 133d, and a plurality of conductive layers 135a, 135b and 135c.

The conductive contact 134a may be disposed in the ILD layer 123′, and may electrically connect to the S/D region 121a. In some embodiments, the conductive contact 134a comprises a barrier layer 131a and a conductive via 133a surrounded by the barrier layer 131a. The conductive via 133a may extend from a top surface 123′T of the ILD layer 123′, through the ILD layer 123′ and the dielectric layer 113′, to the top surface 101T of the semiconductor substrate 101, and the barrier layer 131a may extend into the S/D region 121a. It should be noted that the barrier layer 131a has a first thickness T1 on sidewalls 133aS of the conductive via 133a, and the barrier layer 131a has a second thickness T2 under a bottom surface 133aB of the conductive via 133a. In some embodiments, the barrier layer 131a is formed by an anisotropic deposition process so that the first thickness T1 is less than the second thickness T2. In some embodiments, the anisotropic deposition process for forming the barrier layer 131a includes a physical vapor deposition (PVD) process. Similarly, in some embodiments, the conductive contact 134b comprises a barrier layer 131b and a conductive via 133b surrounded by the barrier layer 131b. Features of the conductive contact 134b are similar to those of the conductive contact 134a, and descriptions thereof are not repeated herein.

The conductive vias 133c and 133d may be disposed in the ILD layer 123′, and may electrically connect to the resistor electrode 115b. In some embodiments, the conductive vias 133c and 133d extend from the top surface 123′T of the ILD layer 123′, through the ILD layer 123′ to the top surface 101T of the semiconductor substrate 101.

The conductive layers 135a, 135b and 135c are disposed over the ILD layer 123′. In particular, the conductive contact 134a is disposed over the S/D region 121a, and the conductive layer 135a is disposed over the conductive contact 134a. The S/D region 121a is electrically connected to the conductive layer 135a through the conductive contact 134a, and the conductive layer 135a is used to electrically connect the S/D region 121a to other devices.

In some embodiments, the conductive contact 134b is disposed over the S/D region 121b, the conductive via 133c is disposed over a portion of the resistor electrode 115b adjacent to the isolation structure 105b, and the conductive layer 135b is disposed over the conductive contact 134b and the conductive via 133c. The conductive contact 134b and the conductive via 133c are covered by the conductive layer 135b. It should be noted that the S/D region 121b of the transistor 100 is electrically connected to the resistor electrode 115b of the resistor 200 through the interconnect structure 137 (i.e., the conductive contact 134b, the conductive layer 135b, and the conductive via 133c). Therefore, the transistor 100 and the resistor 200 are connected in series.

In some embodiments, the conductive via 133d is disposed over a portion of the resistor electrode 115b adjacent to the isolation structure 105c, and the conductive layer 135c is disposed over the conductive via 133d. The resistor electrode 115b is electrically connected to the conductive layer 135c through the conductive via 133d, and the conductive layer 135c is used to electrically connect the resistor 200 to other devices.

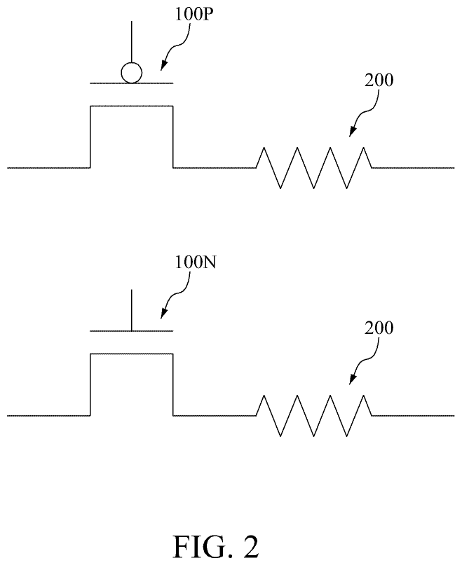

FIG. 2 is a circuit diagram of the semiconductor device structure 300a in FIG. 1. With reference to FIGS. 1 and 2, the transistor 100 of the semiconductor device structure 300a may be a P-type metal-oxide-semiconductor (PMOS) transistor 100P, and the PMOS transistor 100P and the resistor 200 are connected in series. Alternatively, the transistor 100 of the semiconductor device structure 300a may be an N-type metal-oxide-semiconductor (NMOS) transistor 100N, and the NMOS transistor 100N and the resistor 200 are connected in series.

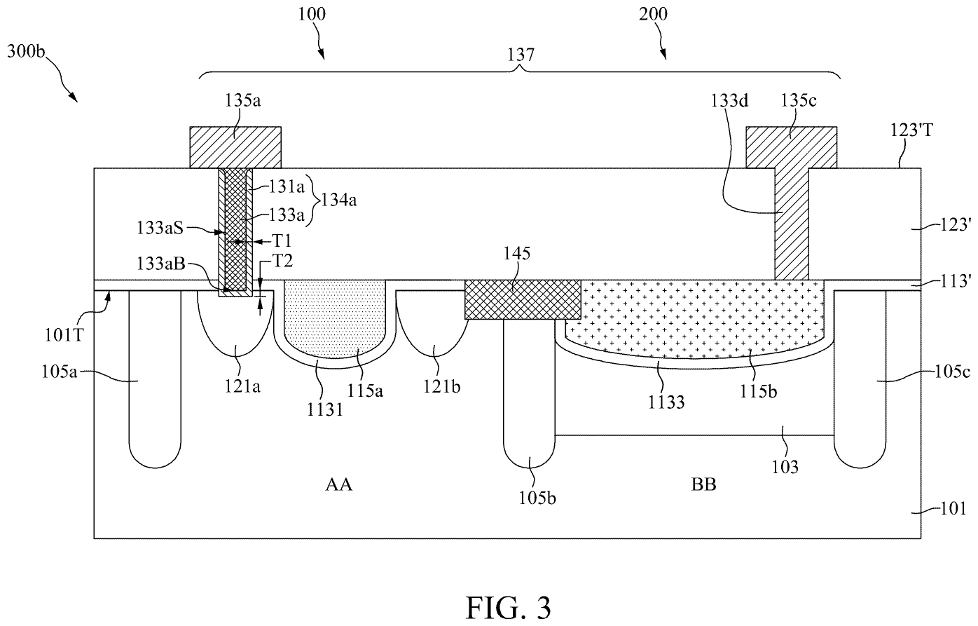

FIG. 3 is a cross-sectional view of a modified semiconductor device structure 300b in accordance with some embodiments of the present disclosure. Similar to the semiconductor device structure 300a of FIG. 1, the semiconductor device structure 300b includes the transistor 100 and the resistor 200. A difference between the semiconductor device structures 300a and 300b lies in the manner of the connection between the transistor 100 and the resistor 200.

Referring to FIG. 3, in accordance with some embodiments, the semiconductor device structure 300b includes a conductive structure 145 disposed in the semiconductor substrate 101 and over the isolation structure 105b. In some embodiments, the conductive structure 145 is covered by the ILD layer 123′, and the conductive structure 145 is disposed between the S/D region 121b of the transistor 100 and the resistor electrode 115b of the resistor 200. It should be noted that the S/D region 121b is electrically connected to the resistor electrode 115b through the conductive structure 145.

In some embodiments, the conductive structure 145 is in direct contact with the S/D region 121b and the resistor electrode 115b, and the conductive structure 145 is not covered by the dielectric layer 113′. Moreover, in some embodiments, the conductive vias 133b and 133c, and the conductive layer 135b are absent from the semiconductor device structure 300b, and the interconnect structure 137 of the semiconductor device structure 300b includes the conductive contact 134a (i.e., the conductive via 133a and the barrier layer 131a), the conductive via 133d, and the conductive layers 135a, 135c. FIG. 2 may be a circuit diagram representing the semiconductor device structure 300b shown in FIG. 3.

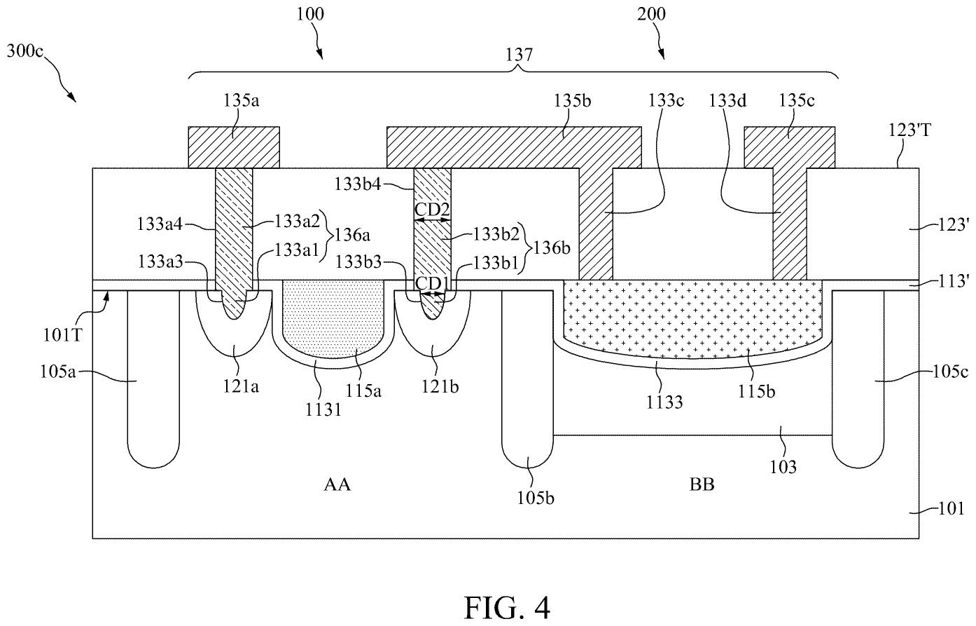

FIG. 4 is a cross-sectional view of another modified semiconductor device structure 300c in accordance with some embodiments of the present disclosure. Similar to the semiconductor device structure 300a of FIG. 1, the semiconductor device structure 300c includes the transistor 100 and the resistor 200. A difference between the semiconductor device structures 300a and 300c is that the conductive contacts 134a and 134b in the semiconductor device structure 300a are replaced by the conductive contacts 136a and 136b in the semiconductor device structure 300c.

Referring to FIG. 4, in accordance with some embodiments, the semiconductor device structure 300c includes the conductive contacts 136a and 136b. The conductive contact 136a includes a lower portion 133al protruding into the S/D region 121a and an upper portion 133a2 interposed between the top surface 101T of the semiconductor substrate 101 and the conductive layer 135a. The conductive contact 136b includes a lower portion 133b1 protruding into the S/D region 121b and an upper portion 133b2 interposed between the top surface 101T of the semiconductor substrate 101 and the conductive layer 135b. The lower portions 133al and 133b1 of the conductive contacts 136a and 136b, extending into the semiconductor substrate 101, can increase a contact area between the conductive contact 136a (or the conductive contact 136b) and the semiconductor substrate 101 over which the transistor 100 is disposed. Therefore, a contact resistance between the gate electrode 115a and the associated conductive contact 136a (or the conductive contact 136b) can be effectively reduced.

In some embodiments, the lower portions 133al and 133b1 of the conductive contacts 136a and 136b in the semiconductor substrate 101 are not in direct contact with any of the isolation structures 105a, 105b and 105c in the semiconductor substrate 101. The lower portions 133a1 and 133b1 of the conductive contacts 136a and 136b, lower than the top surface 101T of the semiconductor substrate 101, can have a first critical dimension CD1, and the upper portions 133a2 and 133b2 of the conductive contacts 136a and 136b, higher than the top surface 101T of the semiconductor substrate 101, can have a second critical dimension CD2 greater than the first critical dimension CD1. In some embodiments, the first critical dimension CD1 gradually decreases at positions of increasing distance from the top surface 101T of the semiconductor substrate 101, while the second critical dimension CD2 is constant. In particular, a peripheral surface 133a3 of the lower portion 133al of the conductive contact 136a is discontinuous with a peripheral surface 133a4 of the upper portion 133a2 of the conductive contact 136a, and a peripheral surface 133b3 of the lower portion 133b1 of the conductive contact 136b is discontinuous with a peripheral surface 133b4 of the upper portion 133b2 of the conductive contact 136b. Notably, the lower portion 133al and the upper portion 133a2 of the conductive contact 136a, including polysilicon, are integrally formed. The lower portion 133b1 and the upper portion 133b2 of the conductive contact 136b, made of a material same as a material of the lower portion 133al and the upper portion 133a2, are integrally formed. FIG. 2 may be a circuit diagram representing the semiconductor device structure 300c shown in FIG. 4.

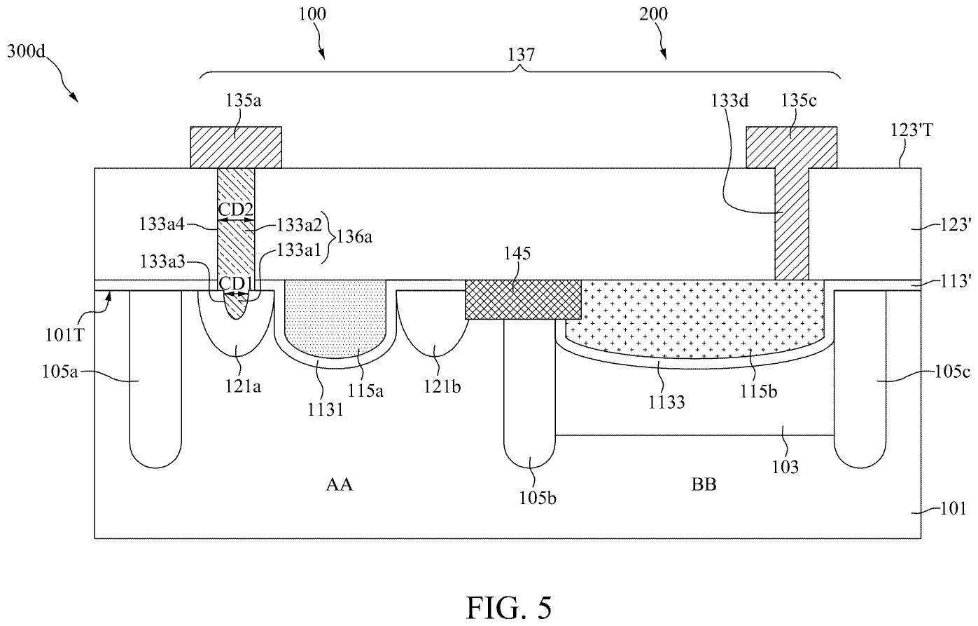

FIG. 5 is a cross-sectional view of yet another modified semiconductor device structure 300d in accordance with some embodiments of the present disclosure. Similar to the semiconductor device structure 300c of FIG. 4, the semiconductor device structure 300d includes the transistor 100 and the resistor 200. A difference between the semiconductor device structures 300c and 300d lies in a manner of connection between the transistor 100 and the resistor 200.

Referring to FIG. 5, in accordance with some embodiments, the semiconductor device structure 300d includes a conductive structure 145 disposed in the semiconductor substrate 101 and over the isolation structure 105b. In some embodiments, the conductive structure 145 is covered by the ILD layer 123′, and the conductive structure 145 is disposed between the S/D region 121b of the transistor 100 and the resistor electrode 115b of the resistor 200. It should be noted that the S/D region 121b is electrically connected to the resistor electrode 115b through the conductive structure 145.

In some embodiments, the conductive structure 145 is in direct contact with the S/D region 121b and the resistor electrode 115b, and the conductive structure 145 is not covered by the dielectric layer 113′. Moreover, in some embodiments, the conductive contact 136b, the conductive via 133c, and the conductive layer 135b are absent from the semiconductor device structure 300d, and the interconnect structure 137 of the semiconductor device structure 300d includes the conductive contact 136a, the conductive via 133d, and the conductive layers 135a and 135c. FIG. 2 may be a circuit diagram representing the semiconductor device structure 300d shown in FIG. 5.

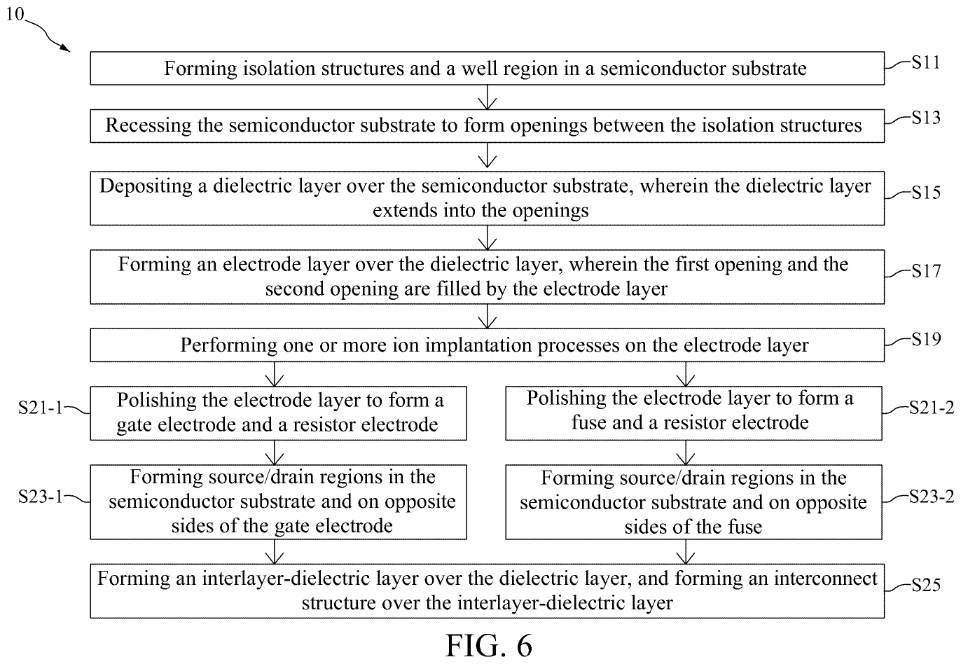

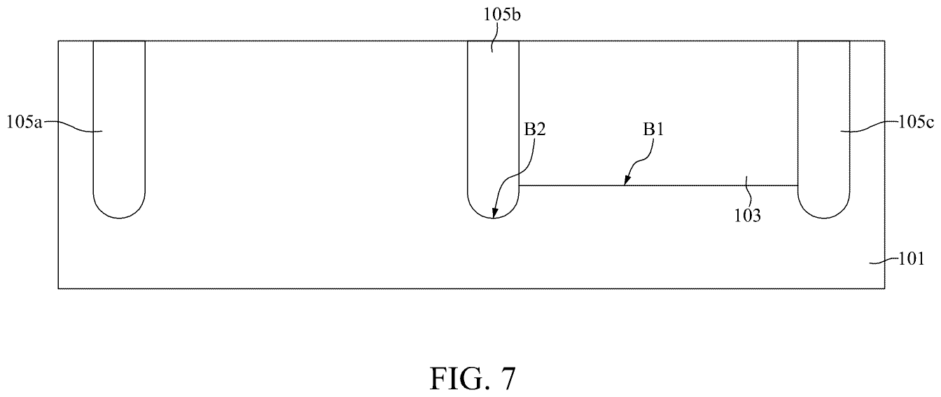

FIG. 6 is a flow diagram illustrating a method 10 for preparing a semiconductor device structure (e.g., the semiconductor device structures 300a, 300b, 300c and 300d), and the method 10 includes steps S11, S13, S15, S17, S19, S21-1, S21-2, S23-1, S23-2 and S25, in accordance with some embodiments. The steps S11 to S25 of FIG. 6 are elaborated in connection with FIGS. 7 to 25.

FIGS. 7 to 17 are cross-sectional views of intermediate stages in the formation of the semiconductor device structure 300a in accordance with some embodiments of the present disclosure.

With reference to FIG. 7, a semiconductor substrate 101 is provided. The semiconductor substrate 101 may be a semiconductor wafer such as a silicon wafer. In some embodiments, the semiconductor substrate 101 may include elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP.

In some embodiments, the semiconductor substrate 101 includes an epitaxial layer. For example, the semiconductor substrate 101 has an epitaxial layer overlying a bulk semiconductor. In some embodiments, the semiconductor substrate 101 is a semiconductor-on-insulator substrate that may include a substrate, a buried oxide layer over the substrate, and a semiconductor layer over the buried oxide layer, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods.

Still referring to FIG. 7, in accordance with some embodiments, a plurality of isolation structures 105a, 105b, 105c are formed in the semiconductor substrate 101, and a well region 103 is formed between the isolation structures 105b and 105c. In some embodiments, the isolation structures 105a, 105b and 105c are shallow trench isolation (STI) structures. In addition, the isolation structures 105a, 105b and 105c may define a plurality of active regions comprising an active region AA disposed between the isolation structure 105a and the isolation structure 105b, and an active region BB disposed between the isolation structure 105b and the isolation structure 105c. The isolation structures 105a, 105b and 105c may be made of silicon oxide, silicon nitride, silicon oxynitride, or another applicable dielectric material, and the formation of the isolation structures 105a, 105b and 105c may include forming a patterned mask over the semiconductor substrate 101, etching the semiconductor substrate 101 to form openings using the patterned mask as a mask, depositing a dielectric material in the openings and over the semiconductor substrate 101, and polishing the dielectric material until the semiconductor substrate 101 is exposed.

In some embodiments, the well region 103 is formed by an ion implantation process, and P-type dopants, such as boron (B), gallium (Ga), or indium (In), or N-type dopants, such as phosphorous (P) or arsenic (As), can be implanted in a portion of the semiconductor substrate 101 between the isolation structures 105b and 105c to form the well region 103. In some embodiments, a patterned mask (not shown) covering the portion of the semiconductor substrate 101 between the isolation structures 105a and 105b may be used in the ion implantation process. The respective step is illustrated as the step S11 in the method 10 shown in FIG. 6.

In some embodiments, the isolation structures 105a, 105b and 105c are formed before the formation of the well region 103. In some other embodiments, the well region 103 is formed before the formation of the isolation structures 105a, 105b and 105c. In addition, a bottom surface B1 of the well region 103 is higher than a bottom surface B2 of the isolation structures 105a, 105b and 105c.

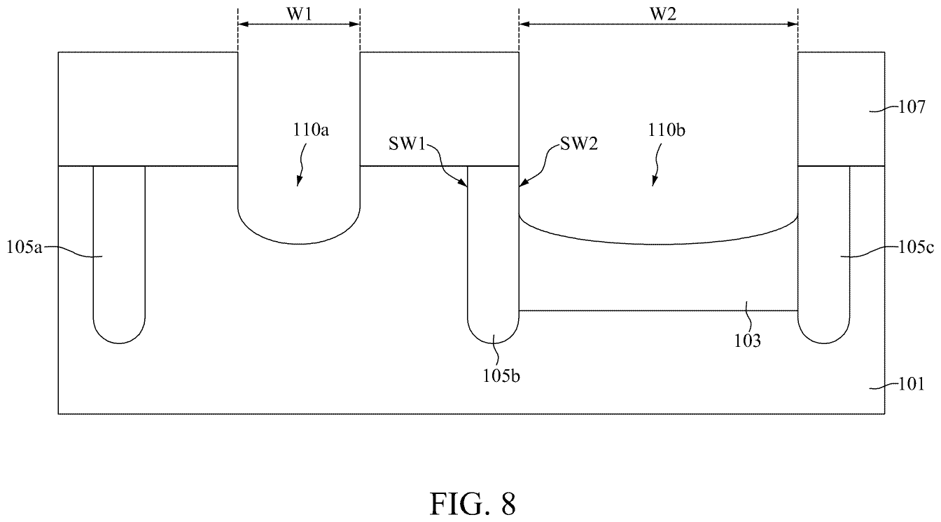

Next, in accordance with some embodiments, a patterned mask 107 is formed over the semiconductor substrate 101, and the semiconductor substrate 101 is recessed to form openings 110a and 110b using the patterned mask 107 as an etching mask, as shown in FIG. 8. In some embodiments, the opening 110a is located between the isolation structures 105a and 105b, and the opening 110b is located between the isolation structures 105b and 105c. The respective step is illustrated as the step S13 in the method 10 shown in FIG. 6.

The patterned mask 107 may be formed by a deposition process and a patterning process. The deposition process for forming the patterned mask 107 may be a chemical vapor deposition (CVD) process, a high-density plasma CVD (HDPCVD) process, a spin-coating process, or another applicable process. The patterning process for forming the patterned mask 107 may include a photolithography process and an etching process. The photolithography process may include photoresist coating (e.g., spin-coating), soft baking, mask aligning, exposure, post-exposure baking, developing the photoresist, rinsing and drying (e.g., hard baking). The etching process may include a dry etching process or a wet etching process.

After the formation of the patterned mask 107, portions of the semiconductor substrate 101 exposed by the patterned mask 107 are partially removed by an etching process. The etching process may be a wet etching process, a dry etching process, or a combination thereof. In some embodiments, the opening 110b is formed by removing an upper portion of the well region 103, such that the opening 110b is formed over the resulting well region 103.

In some embodiments, sidewalls of the isolation structures 105b and 105c are partially exposed by the opening 110b. For example, the isolation structure 105b has a first sidewall SW1 facing the isolation structure 105a and a second sidewall SW2 facing the isolation structure 105c. The first sidewall SW1 is covered by the semiconductor substrate 101 while the second sidewall SW2 is partially exposed by the opening 110b. Moreover, in accordance with some embodiments, the opening 110a has a width W1, and the opening 110b has a width W2, wherein the width W2 is greater than the width W1. After the formation of the openings 110a and 110b, the patterned mask 107 may be removed.

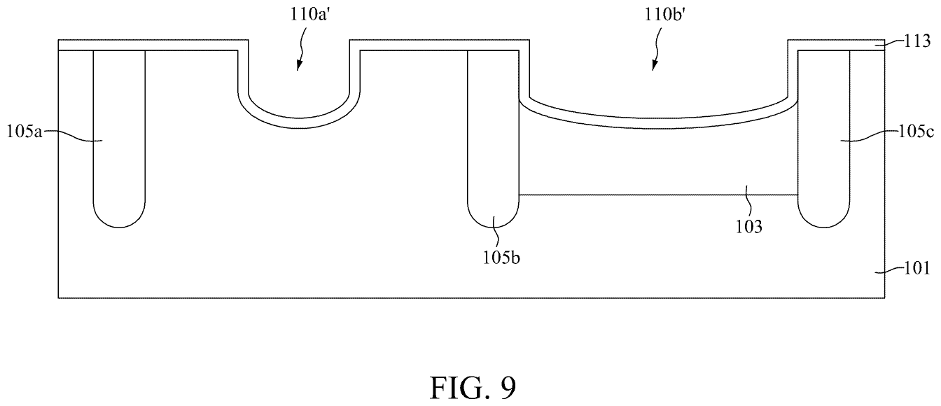

In accordance with some embodiments, the dielectric layer 113 is deposited over the semiconductor substrate 101, as shown in FIG. 9. In some embodiments, the dielectric layer 113 is deposited conformally in the openings 110a and 110b, such as on sidewalls and bottom surfaces of the openings 110a and 110b, and the isolation structures 105a, 105b and 105c are covered by the dielectric layer 113. The respective step is illustrated as the step S15 in the method 10 shown in FIG. 6. After the formation of the dielectric layer 113, reduced openings 110a′ and 110b′ are obtained.

In some embodiments, the dielectric layer 113 includes silicon oxide, silicon nitride, silicon oxynitride, or multilayers thereof. In some embodiments, the dielectric layer 113 is made of a high-k dielectric material, such as hafnium oxide, lanthanum oxide, aluminum oxide, zirconium oxide, or the like. In addition, the dielectric layer 113 may be deposited by a conformal deposition process, such as a CVD process, an atomic layer deposition (ALD) process, a plasma-enhanced CVD (PECVD) process, another applicable process, or a combination thereof.

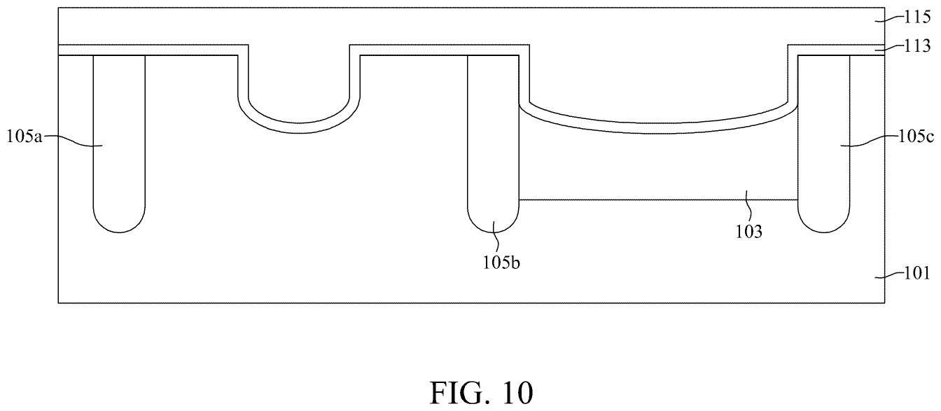

In accordance with some embodiments, after the formation of the dielectric layer 113, an electrode layer 115 is formed over the dielectric layer 113, and the openings 110a′ and 110b′ in the semiconductor substrate 101 are filled by the electrode layer 115, as shown in FIG. 10. The respective step is illustrated as the step S17 in the method 10 shown in FIG. 6.

In some embodiments, the electrode layer 115 is made of a semiconductor material such as polysilicon. In some embodiments, the electrode layer 115 is deposited over the dielectric layer 113 using a CVD process, an ALD process, a sputtering process, or one or more other applicable processes.

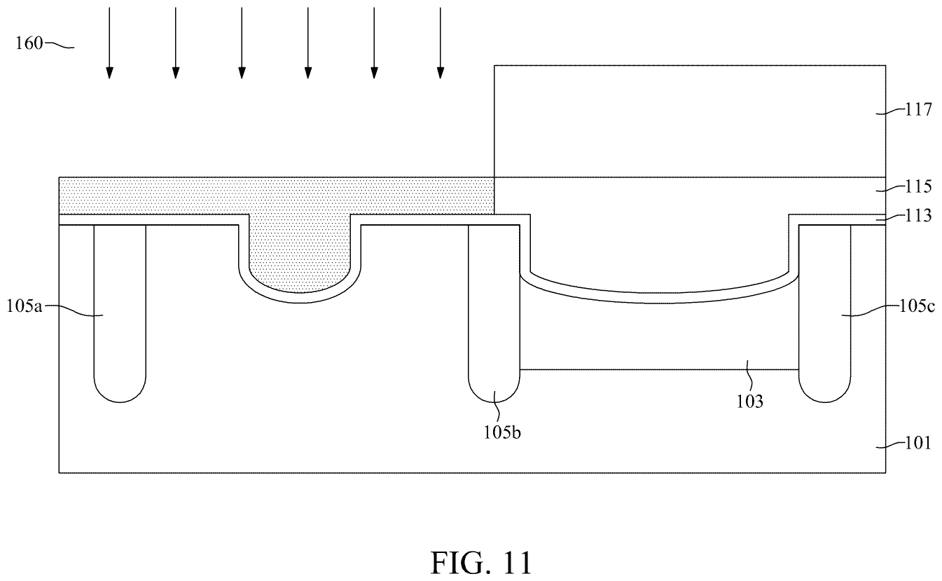

Next, in accordance with some embodiments, a patterned mask 117 is formed to cover the active region BB between the isolation structures 105b and 105c (i.e., the active region of a subsequently-formed resistor 200), and an ion implantation process 160 is performed on a portion of the electrode layer 115 exposed by the patterned mask 117, as shown in FIG. 11. In some embodiments, a portion of the electrode layer 115 over the well region 103 is covered by the patterned mask 117.

Some processes used to form the patterned mask 117 are similar to, or same as, those used to form the patterned mask 107 (see FIG. 8), and details thereof are not repeated. During the ion implantation process 160, P-type dopants, such as boron (B), gallium (Ga), or indium (In), or N-type dopants, such as phosphorous (P) or arsenic (As), are introduced into the electrode layer 115 using the patterned mask 117 as an implantation mask. After the ion implantation process 160, the patterned mask 117 may be removed.

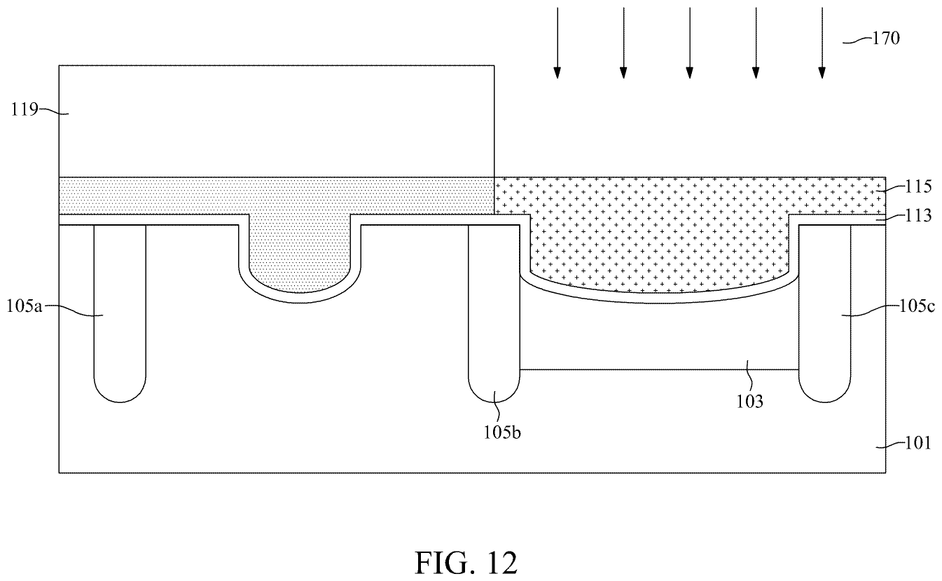

Next, in accordance with some embodiments, a patterned mask 119 is formed to cover the active region AA between the isolation structures 105a and 105b (i.e., the active region of a subsequently-formed transistor 100), and an ion implantation process 170 is performed on a portion of the electrode layer 115 exposed by the patterned mask 119, as shown in FIG. 12. In alternative embodiments, the ion implantation process 170 is performed before the ion implantation process 160. The respective step is illustrated as the step S19 in the method 10 shown in FIG. 6.

Some processes used to form the patterned mask 119 are similar to, or same as, those used to form the patterned mask 107 (see FIG. 8), and details thereof are not repeated. During the ion implantation process 170, P-type dopants, such as boron (B), gallium (Ga), or indium (In), or N-type dopants, such as phosphorous (P) or arsenic (As), are introduced into the electrode layer 115 using the patterned mask 119 as an implantation mask.

It should be noted that, in accordance with some embodiments, for a purpose of increased conductivity, the portion of the electrode layer 115 between the isolation structures 105a and 105b is heavily doped compared to the portion of the electrode layer 115 between the isolation structures 105b and 105c. In some embodiments, a dose amount of the ion implantation process 160 is greater than a dose amount of the ion implantation process 170. After the ion implantation process 170 is completed, the patterned mask 119 may be removed. In addition, an annealing process may be used to activate implanted dopants.

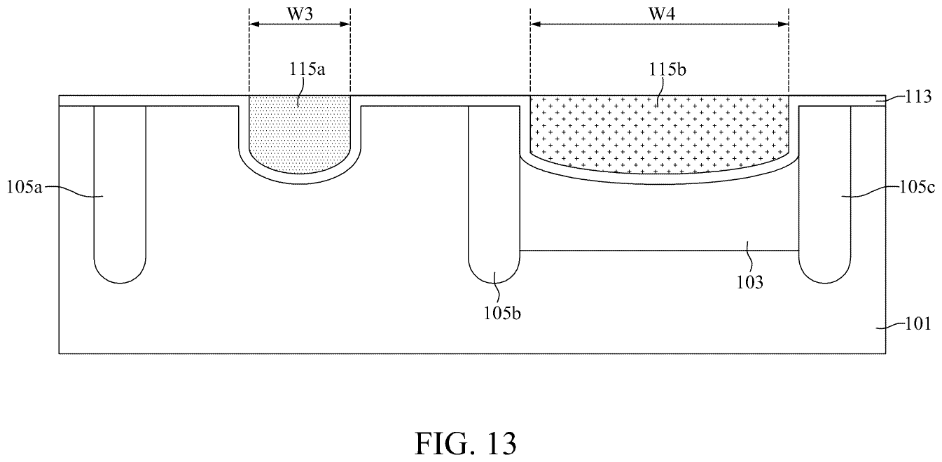

Subsequently, in accordance with some embodiments, a polishing process is performed on the electrode layer 115 to form a gate electrode 115a in the opening 110a′ (see FIG. 9) and a resistor electrode 115b in the opening 110b′ (see FIG. 9), as shown in FIG. 13. In some embodiments, the polishing process is performed until the dielectric layer 113 is exposed, and an excess portion of the electrode layer 115 over the dielectric layer 113 is removed. The respective step is illustrated as the step S21-1 in the method 10 shown in FIG. 6.

In some embodiments, the polishing process is a chemical mechanical polishing (CMP) process. In some embodiments, the gate electrode 115a has a width W3, and the resistor electrode 115b has a width W4, wherein the width W4 is greater than the width W3. Moreover, a required conductivity of the gate electrode 115a is greater than a required conductivity of the resistor electrode 115b. Therefore, a dopant concentration of the gate electrode 115a is greater than a dopant concentration of the resistor electrode 115b.

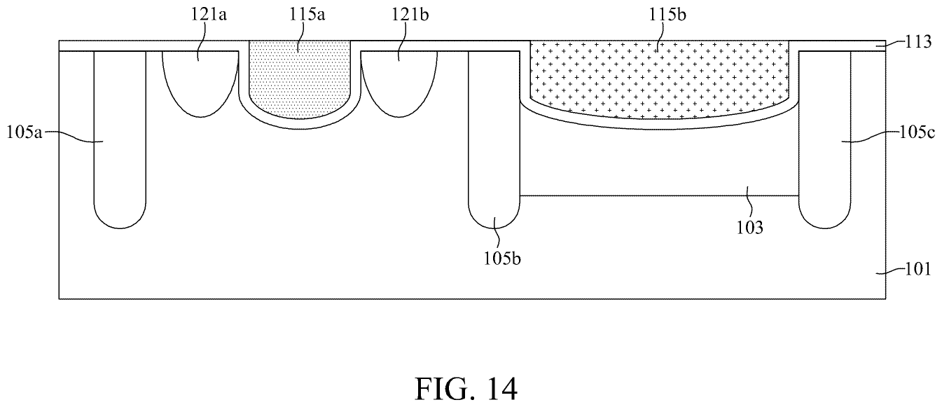

In accordance with some embodiments, after the formation of the gate electrode 115a and the resistor electrode 115b, S/D regions 121a and 121b are formed in the semiconductor substrate 101 and on opposite sides of the gate electrode 115a, as shown in FIG. 14. The S/D regions 121a and 121b may be formed by ion implantation and/or diffusion, and an annealing process, such as a rapid thermal annealing (RTA) process, may be used to activate implanted dopants. The respective step is illustrated as the step S23-1 in the method 10 shown in FIG. 6.

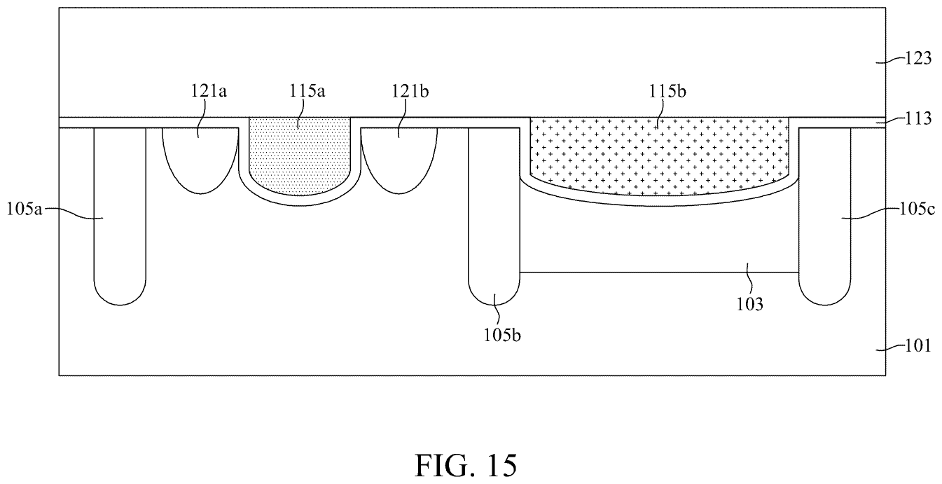

In some embodiments, the S/D regions 121a and 121b and the well region 103 are doped with one or more P-type dopants, such as boron (B), gallium (Ga), or indium (In). In alternative embodiments, the S/D regions 121a and 121b and the well region 103 are doped with one or more N-type dopants, such as phosphorous (P) or arsenic (As). In accordance with some embodiments, an ILD layer 123 is formed over the structure of FIG. 14, as shown in FIG. 15. In some embodiments, the ILD layer 123 is made of silicon oxide, silicon nitride, silicon oxynitride, phosphosilicate glass (PSG), borophosphosilicate glass (BPSG), low-k dielectric material, and/or other applicable dielectric materials. In addition, the ILD layer 123 may be formed by a CVD process, a physical vapor deposition (PVD) process, an ALD process, a spin-coating process, or another applicable process.

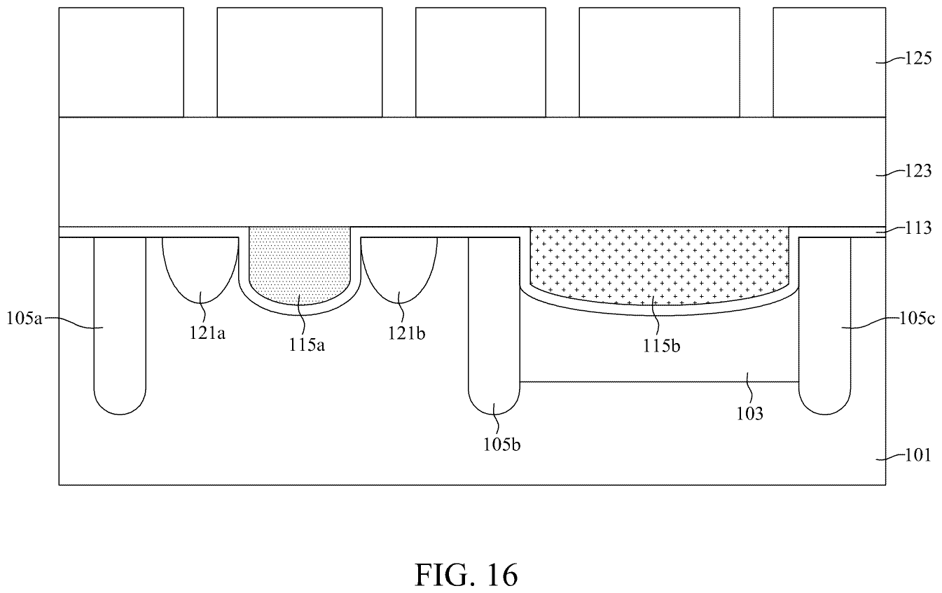

Next, in accordance with some embodiments, a patterned mask 125 is formed over the ILD layer 123, as shown in FIG. 16. In some embodiments, the patterned mask 125 has openings, and portions of the ILD layer 123 are exposed by the openings of the patterned mask 125. Some processes used to form the patterned mask 125 are similar to, or same as, those used to form the patterned mask 107 (see FIG. 8), and details thereof are not repeated.

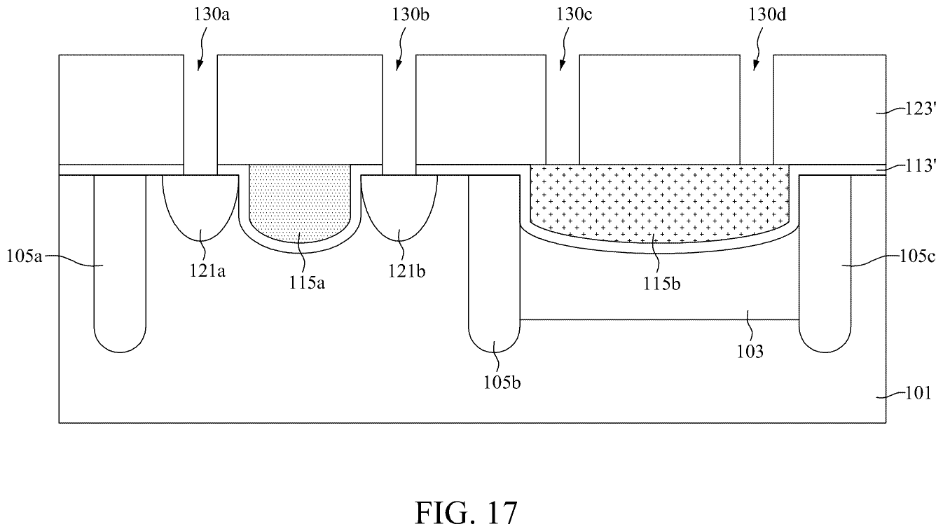

Next, in accordance with some embodiments, an etching process is performed on the ILD layer 123 and the dielectric layer 113 using the patterned mask 125 as a mask, as shown in FIG. 17. After the etching process, openings 130a, 130b, 130c and 130d are formed. In some embodiments, the openings 130a and 130b penetrate through the ILD layer 123 and the dielectric layer 113, and the S/D regions 121a and 121b are exposed by the openings 130a and 130b, respectively. In some embodiments, the openings 130c and 130d penetrate through the ILD layer 123, and the resistor electrode 115b is partially exposed by the openings 130c and 130d. After the formation of the openings 130a, 130b, 130c and 130d, an etched ILD layer 123′ and an etched dielectric layer 113′ are obtained.

Referring back to FIG. 1, in accordance with some embodiments, an interconnect structure 137 is formed over the ILD layer 123′. As mentioned above, the interconnect structure 137 includes conductive contacts 134a and 134b, conductive vias 133c and 133d, and conductive layers 135a, 135b and 135c. In some embodiments, the conductive contacts 134a and 134b are respectively formed in the openings 130a and 130b, wherein the conductive contact 134a includes a barrier layer 131a covering sidewalls and a bottom surface of the opening 130a (see FIG. 17), and a conductive via 133a disposed over and surrounded by the barrier layer 131a, and wherein the conductive contact 134b includes a barrier layer 131b covering sidewalls and a bottom surface of the opening 130b (see FIG. 17), and a conductive via 133b disposed over and surrounded by the barrier layer 131b. In some embodiments, the conductive vias 133c and 133d are respectively formed in the openings 130c and 130d, and the conductive layers 135a, 135b and 135c are formed over the ILD layer 123′ to cover the conductive contacts 134a and 134b and the conductive vias 133c and 133d. The respective step is illustrated as the step S25 in the method 10 shown in FIG. 6.

In some embodiments, the conductive vias 133a, 133b, 133c and 133d and the conductive layers 135a, 135b and 135c of the interconnect structure 137 are made of copper (Cu), copper alloy, aluminum (Al), aluminum alloy, tungsten (W), tungsten alloy, titanium (Ti), titanium alloy, tantalum (Ta), tantalum alloy, or a combination thereof. Alternatively, other applicable conductive materials may be used. In some embodiments, the barrier layers 131a and 131b of the conductive contacts 136a and 136b of the interconnect structure 137 are made of titanium (Ti), titanium nitride (TiN), or a combination thereof. Moreover, the interconnect structure 137 may be formed by one or more deposition processes and a subsequent patterning process. The deposition process may be a CVD process, a PVD process, an ALD process, a metal organic CVD (MOCVD) process, a sputtering process, a plating process, or another applicable deposition process, and the patterning process may include a photolithography process and an etching process. In addition, in some embodiments, the deposition process of the barrier layers 131a and 131b of the conductive contacts 136a and 136b of the interconnect structure 137 may be an anisotropic deposition process that includes a physical vapor deposition (PVD) process. In some embodiments, the interconnect structure 137 includes multilayers.

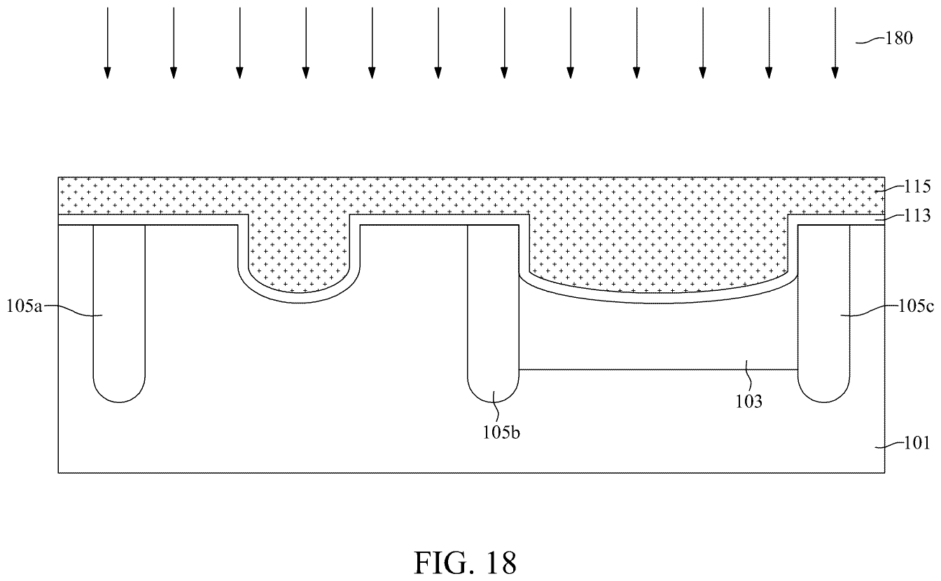

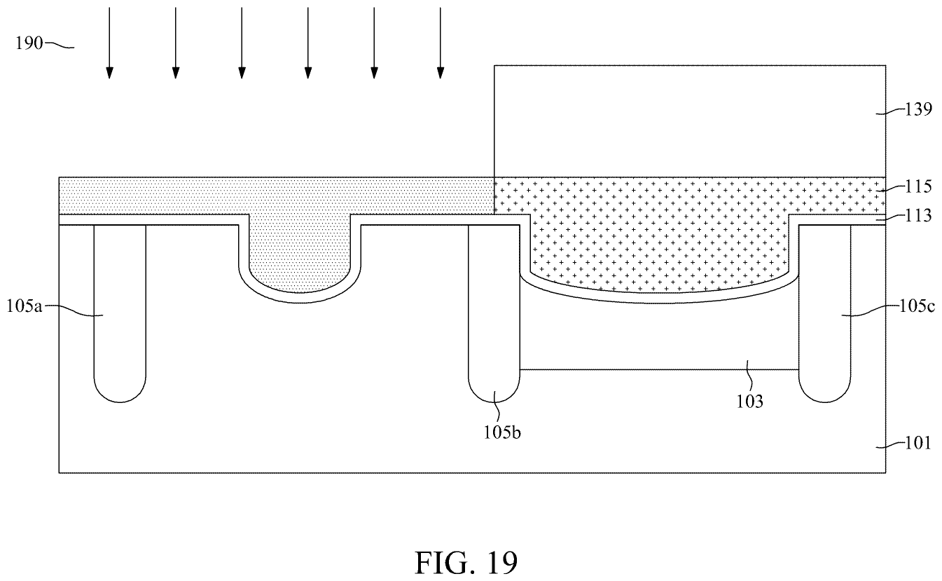

FIGS. 18 to 19 are cross-sectional views of intermediate stages in the formation of the semiconductor device structure 300a, in accordance with some other embodiments of the present disclosure.

In accordance with some alternative embodiments, the ion implantation processes 160 and 170 (see FIGS. 11 and 12) are replaced by ion implantation processes 180 and 190, as shown in FIGS. 18 and 19. With reference to FIG. 16, the ion implantation process 180 is performed on the structure of FIG. 10 in the absence of an implantation mask.

Subsequently, in accordance with some embodiments, a patterned mask 139 is formed to cover the active region BB between the isolation structures 105b and 105c (i.e., the active region of the subsequently-formed resistor 200), and the ion implantation process 190 is performed on a portion of the electrode layer 115 exposed by the patterned mask 139, as shown in FIG. 19. Some processes used to form the patterned mask 139 are similar to, or same as, those used to form the patterned mask 107 (see FIG. 8), and details thereof are not repeated.

It should be noted that the portion of the electrode layer 115 between the isolation structures 105a and 105b is subjected to one more ion implantation than the portion of the electrode layer 115 between the isolation structures 105b and 105c. Therefore, a dopant concentration of the portion of the electrode layer 115 between the isolation structures 105a and 105b is greater than a dopant concentration of the portion of the electrode layer 115 between the isolation structures 105b and 105c. As a result, a dopant concentration of the gate electrode 115a is greater than a dopant concentration of the resistor electrode 115b in the resulting semiconductor device structure 300a.

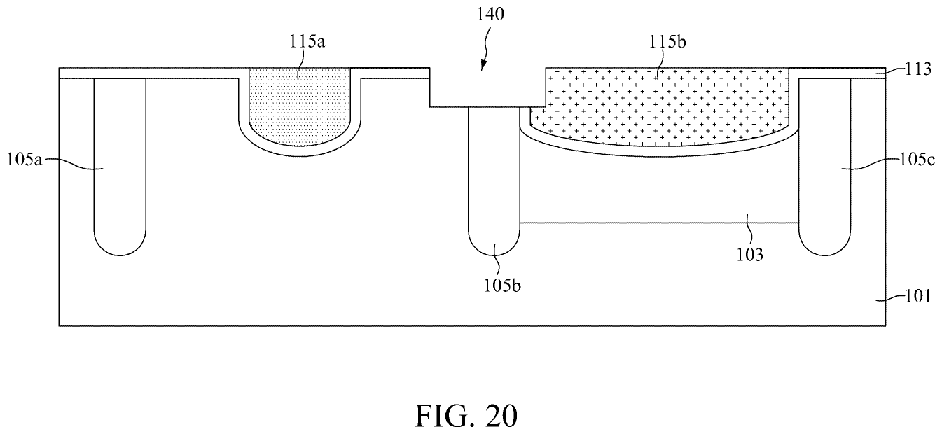

FIGS. 20 to 22 are cross-sectional views of intermediate stages in the formation of a modified semiconductor device structure 300b in accordance with some embodiments of the present disclosure.

Referring to FIG. 20, in accordance with some embodiments, an upper portion of the isolation structure 105b is etched to form an opening 140 after the electrode layer 115 is polished (see FIG. 13). The opening 140 may be formed using a patterned mask (not shown) as an etching mask. In some embodiments, the dielectric layer 113, the semiconductor substrate 101, and the resistor electrode 115b are partially etched to form the opening 140.

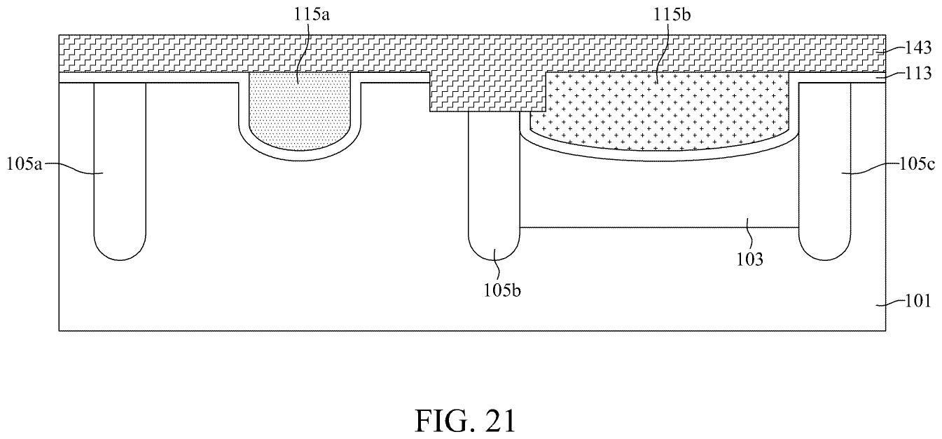

Next, in accordance with some embodiments, a conductive layer 143 is formed over the dielectric layer 113, and the opening 140 is filled by the conductive layer 143, as shown in FIG. 21. In some embodiments, the conductive layer 143 is in direct contact with the resistor electrode 115b.

In some embodiments, the conductive layer 143 is made of copper (Cu), copper alloy, aluminum (Al), aluminum alloy, tungsten (W), tungsten alloy, titanium (Ti), titanium alloy, tantalum (Ta), tantalum alloy, another applicable conductive material, or a combination thereof. In addition, the conductive layer 143 may be formed by a CVD process, a PVD process, an ALD process, a plating process, a sputtering process, or another applicable process.

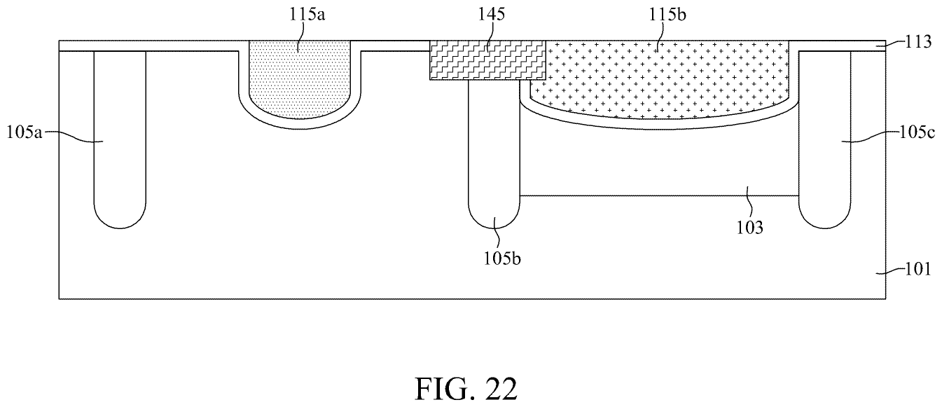

After the formation of the conductive layer 143, in accordance with some embodiments, a planarization process is performed to expose the gate electrode 115a and the resistor electrode 115b, and the conductive structure 145 is formed in the semiconductor substrate 101 and over the isolation structure 105b, as shown in FIG. 22. The planarization process for forming the conductive structure 145 may include a CMP process, a grinding process, an etching process, another suitable process, or a combination thereof.

After the planarization process, in accordance with some embodiments, the top surfaces of the dielectric layer 113, the gate electrode 115a, the resistor electrode 115b, and the conductive structure 145 are substantially coplanar. Within the context of this disclosure, the word “substantially” means preferably at least 90%, more preferably 95%, even more preferably 98%, and most preferably 99%.

Subsequently, the processes of FIGS. 14 to 17 used to form the semiconductor device structure 300a are performed on the structure of FIG. 22. As mentioned above, since the connecting fashion of the transistor 100 and the resistor 200 are different between the semiconductor device structures 300a and 300b, the openings 130b and 130c (see FIG. 17) are not formed in the ILD layer 123′, such that the interconnect structure 137 of the semiconductor device structure 300b (see FIG. 3) only includes the conductive contact 136a, the conductive via 133d, and the conductive layers 135a, 135c. However, in some other embodiments, the interconnect structure 137 of the semiconductor device structure 300b includes other conductive elements for electrically connecting with other devices.

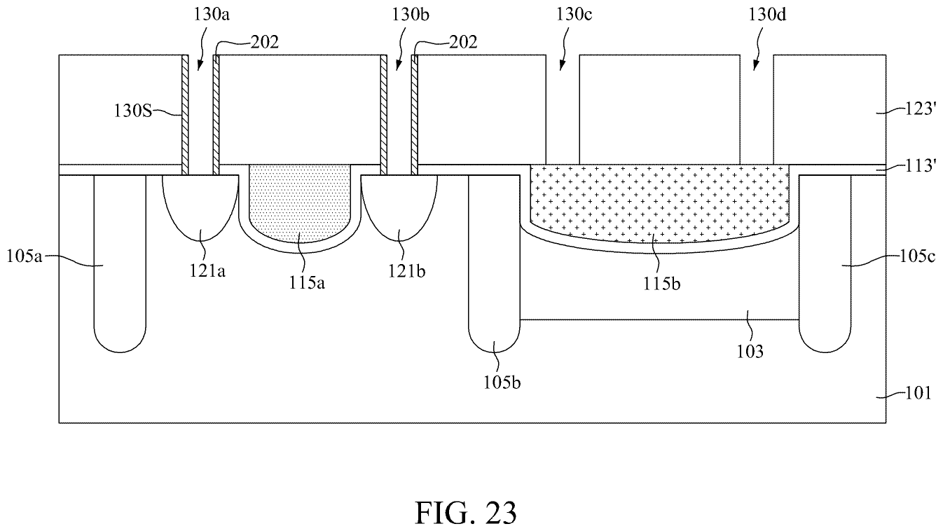

FIGS. 23 to 25 are cross-sectional views of intermediate stages in the formation of a semiconductor device structure 300c shown in FIG. 4 in accordance with some embodiments of the present disclosure. It should be noted that operations for forming the semiconductor device structure 300c before the structure shown in FIG. 23 are substantially same as the operations for forming the semiconductor device structure 300a shown in FIGS. 7 to 17 (respective steps are illustrated as the steps S11 to S23 in the method shown in FIG. 6). Accordingly, detailed descriptions are provided above and are not repeated.

With reference to FIG. 23, in accordance with some embodiments, a sacrificial liner 202 is formed on the sidewalls of the openings 130a and 130b. The formation of the sacrificial liner 202 may include forming a patterned mask (not shown) to cover the active region BB between the isolation structures 105b and 105c; conformally depositing a sacrificial film (not shown) in the openings 130a and 130b, on the etched ILD layer 123′ and on the patterned mask; performing a removal process, such as an anisotropic etching process, to remove horizontal portions of the sacrificial film in the openings 130a and 130b, and horizontal portions on the etched ILD layer 123′ and on the patterned mask, while vertical portions of the sacrificial film are left on the sidewalls of the openings 130a and 130b and on the patterned mask; and performing a planarization process to remove the patterned mask and the vertical portion of the sacrificial film on the patterned mask. The sacrificial liner 202 is thereby formed in the openings 130a and 130b. In some embodiments, the sacrificial film includes a dielectric material having etch characteristics different from those of the semiconductor substrate 101. For example, the sacrificial film can include nitride and can be deposited using a CVD process, an ALD process, or the like.

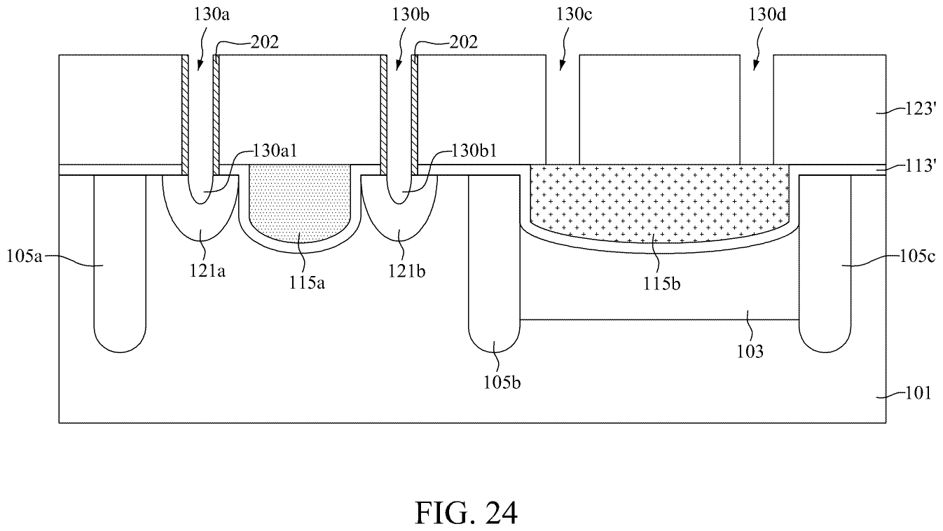

With reference to FIG. 24, in accordance with some embodiments, portions of the semiconductor substrate 101 exposed through the openings 130a and 130b (i.e., the S/D regions 121a and 121b) are etched away. As a result, contact holes 130al and 130b1 respectively connected to the openings 130a and 130b are formed. The portions of the semiconductor substrate 101 exposed through the openings 130a and 130b are anisotropically dry-etched, using at least one reactive ion etching (RIE) process, for example, through the openings 130a and 130b to form the contact holes 130al and 130b1 in the semiconductor substrate 101. The sacrificial liner 202 functions as a mask during the etching of the semiconductor substrate 101.

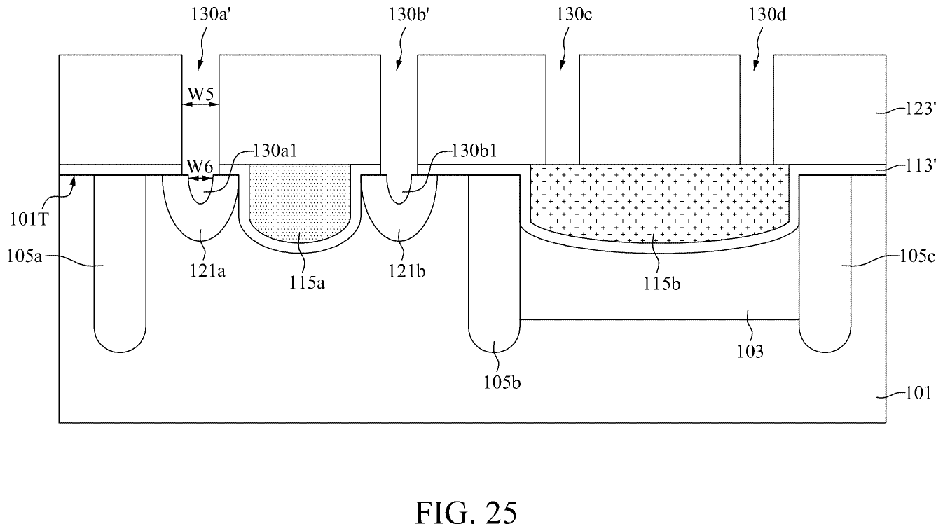

With reference to FIG. 25, after the formation of the contact holes 130al and 130b1, the sacrificial liners 202 are removed, and openings 130a′ and 130b′ are formed at the positions of the openings 130a and 130b, respectively. The sacrificial liners 202 are removed using a stable process such as a wet etching process. As shown in FIG. 25, the openings 130a′ and 130b′ have a substantially uniform first width W5, and the contact holes 130al and 130b1 have a non-uniform width W6. In some embodiments, the width W6 gradually decreases at positions of increasing distance from an upper surface 101T of the semiconductor substrate 101.

Referring back to FIG. 4, in accordance with some embodiments, the interconnect structure 137 is formed over the ILD layer 123′. As mentioned above, the interconnect structure 137 includes the conductive contacts 136a and 136b, the conductive vias 133c and 133d, and the conductive layers 135a, 135b and 135c. In some embodiments, the conductive contacts 136a and 136b are formed in the openings 130a′ and 130b′, and in the contact holes 130al and 130b1 (see FIG. 25), respectively. The conductive contact 136a includes a lower portion 133al disposed in the contact hole 130al′ and protruding into the S/D region 121a, and an upper portion 133a2 disposed in the opening 130al and interposed between the top surface 101T of the semiconductor substrate 101 and the conductive layer 135a. The conductive contact 136b includes a lower portion 133b1 disposed in the contact hole 130b1 and protruding into the S/D region 121b, and an upper portion 133b2 disposed in the opening 130bl′ and interposed between the top surface 101T of the semiconductor substrate 101 and the conductive layer 135b. In some embodiments, the conductive vias 133c and 133d are respectively formed in the openings 130c and 130d, and the conductive layers 135a, 135b and 135c are formed over the ILD layer 123′ to cover the conductive contacts 136a and 136b and the conductive vias 133c and 133d. The respective step is illustrated as the step S25 in the method 10 shown in FIG. 6.

Embodiments of the semiconductor device structures 300a, 300b, 300c and 300d are provided in the disclosure. The semiconductor device structures 300a, 300b, 300c and 300d include the transistor 100 (e.g., the PMOS transistor 100P or the NMOS transistor 100N) and the resistor 200 connected in series and formed by an integrated process flow. Particularly, the gate electrode 115a of the transistor 100 and the resistor electrode 115b of the resistor 200 are formed in the semiconductor substrate 101 by same process steps. Therefore, the resistor 200 may exhibit high sheet resistance without using additional masks or process steps. As a result, associated costs may be reduced, and a performance of the semiconductor device structures 300a, 300b, 300c and 300d may be improved.

One aspect of the present disclosure provides a semiconductor device. The semiconductor device comprises a substrate; a transistor and a resistor disposed in the substrate; a plurality of isolation structures disposed in the substrate, wherein the transistor is disposed between a pair of isolation structures and the resistor is disposed between another pair of isolation structures; a dielectric layer disposed over the substrate; and an interconnect structure disposed over and electrically connected to the transistor and the resistor.

Another aspect of the present disclosure provides a semiconductor device. The semiconductor device comprises a plurality of source/drain (S/D) regions disposed in a substrate; a dielectric layer disposed over the source/drain regions; and a conductive contact penetrating through the dielectric layer into the source/drain regions. The conductive contact comprises a conductive via and a barrier layer covering sidewalls and a bottom surface of the conductive via. A first thickness of the barrier layer on the sidewalls of the conductive via is less than a second thickness of the barrier layer under the bottom surface of the conductive via.

Another aspect of the present disclosure provides a semiconductor device. The semiconductor device comprises a substrate having a plurality of isolation structures disposed therein, wherein the plurality of isolation structures define a first active region and a second active region of the substrate; a plurality of source/drain (S/D) regions disposed in the first active region and a well region disposed in the second active region; a gate electrode and a resistor electrode disposed in the substrate, wherein the gate electrode is disposed between a pair of source/drain (S/D) regions, and the resistor electrode is disposed over the well region; a dielectric layer disposed over the substrate, wherein a first portion of the dielectric layer is disposed between the gate electrode and the substrate, and a second portion of the dielectric layer is disposed between the resistor electrode and the substrate; an interlayer-dielectric (ILD) layer disposed over the dielectric layer, the gate electrode and the resistor electrode; a plurality of conductive contacts disposed on the plurality of source/drain (S/D) regions; and a plurality of conductive layers disposed over the ILD layer. The embodiments of the present disclosure have some advantageous features. By forming a gate electrode of a transistor and a resistor electrode of a resistor in a semiconductor substrate using same process steps, the resistor may exhibit high sheet resistance without using additional masks or process steps. This significantly reduces costs, and a performance of the semiconductor device structure including the transistor and the resistor is improved.

Another aspect of the present disclosure provides a semiconductor device. The semiconductor device comprises a source/drain (S/D) region disposed in a substrate; a conductive layer disposed over the substrate; and a conductive contact comprising a lower portion protruding into the S/D region and an upper portion disposed on the lower portion and interposed between a top surface of the substrate and the conductive layer.

Another aspect of the present disclosure provides a method of fabricating a semiconductor device. The method comprises providing a semiconductor substrate; forming a plurality of isolation structures and a well region in the semiconductor substrate; recessing the semiconductor substrate to form a plurality of openings between the isolation structures; depositing a dielectric layer over the semiconductor substrate to form a first opening and a second opening in the substrate, wherein the dielectric layer extends into the first opening and the second opening; forming an electrode layer over the dielectric layer, wherein the first opening and the second opening are filled by the electrode layer; performing one or more ion implantation process on the electrode layer; polishing the electrode layer to form a gate electrode and a resistor electrode; forming a plurality of source/drain regions in the semiconductor substrate and on opposite sides of the gate electrode; forming an interlayer-dielectric layer over the dielectric layer; etching the interlayer-dielectric layer and the dielectric layer to form a third opening and a fourth opening in the interlayer-dielectric layer, and form an etched interlayer-dielectric layer over the semiconductor substrate; forming a plurality of conductive contacts in the third opening, and forming a plurality of conductive vias in the fourth opening; and forming an interconnect structure over the etched interlayer-dielectric layer, the conductive contacts and the conductive vias.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device structure, comprising:
a substrate having a plurality of isolation structures disposed therein, wherein the plurality of isolation structures define a first active region and a second active region of the substrate;
a plurality of source/drain (S/D) regions disposed in the first active region and a well region disposed in the second active region;
a gate electrode and a resistor electrode disposed in the substrate, wherein the gate electrode is disposed between a pair of the source/drain (S/D) regions, and the resistor electrode is disposed over the well region;
a dielectric layer disposed over the substrate, wherein a first portion of the dielectric layer is disposed between the gate electrode and the substrate, and a second portion of the dielectric layer is disposed between the resistor electrode and the substrate;
an interlayer-dielectric (ILD) layer disposed over the dielectric layer, the gate electrode and the resistor electrode;
a plurality of conductive contacts disposed on the plurality of source/drain (S/D) regions; and
a plurality of conductive layers disposed over the ILD layer.

2. The semiconductor device structure of claim 1, wherein each of the conductive contacts comprises:
a lower portion protruding into a corresponding S/D region; and
an upper portion disposed on the lower portion and interposed between a top surface of the substrate and the conductive layers.

3. The semiconductor device structure of claim 2, wherein the lower portions of the conductive contacts in the substrate are free of direct contact with any of the plurality of isolation structures in the substrate.

4. The semiconductor device structure of claim 2, wherein the lower portions of the conductive contacts comprise a first critical dimension and the upper portions of the conductive contacts comprise a second critical dimension, wherein the second critical dimension is greater than the first critical dimension.

5. The semiconductor device structure of claim 4, wherein the first critical dimension of the lower portions gradually decreases at positions of increasing distance from the top surface of the substrate, while the second critical dimension of the upper portions is constant.

6. The semiconductor device structure of claim 4, wherein peripheral surfaces of the lower portions of the conductive contacts are respectively discontinuous with peripheral surfaces of the upper portions of the conductive contacts.

7. The semiconductor device structure of claim 1, wherein the well region adjoins the isolation structures in the second active region.

8. The semiconductor device structure of claim 1, further comprising a plurality of conductive vias disposed over and electrically connected to the resistor electrode.

9. The semiconductor device structure of claim 8, wherein the conductive contacts, the conductive vias and the conductive layers together configure an interconnect structure.

10. A semiconductor device structure, comprising:
a source/drain (S/D) region disposed in a substrate;
a conductive layer disposed over the substrate; and
a conductive contact comprising a lower portion protruding into the S/D region, and an upper portion disposed on the lower portion and interposed between a top surface of the substrate and the conductive layer.

11. The semiconductor device structure of claim 10, wherein the lower portion of the conductive contact comprises a first critical dimension and the upper portion of the conductive contact comprises a second critical dimension, wherein the second critical dimension is greater than the first critical dimension.

12. The semiconductor device structure of claim 10, further comprising a plurality of isolation structures disposed in the substrate, wherein the lower portion of the conductive contact in the substrate is free of direct contact with any of the plurality of isolation structures in the substrate.

13. The semiconductor device structure of claim 12, wherein the first critical dimension of the lower portion gradually decreases at positions of increasing distance from the top surface of the substrate, while the second critical dimension of the upper portion is constant.

14. The semiconductor device structure of claim 13, wherein a peripheral surface of the lower portion of the conductive contact is discontinuous with a peripheral surface of the upper portion of the conductive contact.

15. A method of fabricating a semiconductor device, comprising:
providing a semiconductor substrate;
forming a plurality of isolation structures and a well region in the semiconductor substrate;
recessing the semiconductor substrate to form a plurality of openings between the isolation structures;
depositing a dielectric layer over the semiconductor substrate to form a first opening and a second opening in the substrate, wherein the dielectric layer extends into the first opening and the second opening;
forming an electrode layer over the dielectric layer, wherein the first opening and the second opening are filled by the electrode layer;
performing one or more ion implantation process on the electrode layer;
polishing the electrode layer to form a gate electrode and a resistor electrode;
forming a plurality of source/drain regions in the semiconductor substrate and on opposite sides of the gate electrode;
forming an interlayer-dielectric layer over the dielectric layer;
etching the interlayer-dielectric layer and the dielectric layer to form a third opening and a fourth opening in the interlayer-dielectric layer, and form an etched interlayer-dielectric layer over the semiconductor substrate;
forming a plurality of conductive contacts in the third opening, and forming a plurality of conductive vias in the fourth opening; and
forming an interconnect structure over the etched interlayer-dielectric layer, the conductive contacts and the conductive vias.

16. The method of claim 15, wherein the formation of the conductive contacts in the third opening, and the formation of the conductive vias in the fourth opening comprises:
forming a sacrificial liner on sidewalls of the third opening;
performing an etching process to form a contact hole in the source/drain regions and connected to the third opening;
removing the sacrificial liner to form the fifth opening; and
filling a conductive material in the fourth opening, the fifth opening and the contact hole.

17. The method of claim 15, wherein the conductive contact comprises a lower portion disposed in the S/D region and an upper portion disposed over the lower portion, wherein the upper portion interposed between a top surface of the semiconductor substrate and the interconnect structure.

18. The method of claim 17, wherein the lower portion comprise a first critical dimension and the upper portion comprise a second critical dimension, wherein the second critical dimension is greater than the first critical dimension.

19. The method of claim 17, wherein the first critical dimension of the lower portion gradually decreases at positions of increasing distance from the top surface of the substrate, while the second critical dimension of the upper portion is constant.
